(19) United States
(12) Patent Application Publication
(10) Pub. No.: US 2009/0102050 A1
(43) Pub. Date: Apr. 23, 2009

(54) SOLDER BALL DISPOSING SURFACE STRUCTURE OF PACKAGE SUBSTRATE

(75) Inventor: Shih-Ping HSU, Hsin-Chu (TW)

Correspondence Address: FULBRIGHT AND JAWORSKI LLP, 555 S. FLOWER STREET, 41ST FLOOR, LOS ANGELES, CA, 90071, US

(73) Assignee: PHOENIX PRECISION TECHNOLOGY CORPORATION, Hsin-Chu (TW)

(21) Appl. No.: 11/873,603

(22) Filed: Oct. 17, 2007

(51) Int. Cl. H01L 23/48

(52) U.S. Cl. 257/738; 257/E23.069

(57) ABSTRACT

A solder ball disposing surface structure of a package substrate is disclosed, wherein a package substrate has a chip disposing surface with a first circuit layer, an opposed solder ball disposing surface with a second circuit layer, and a first insulative protection layer formed on the chip disposing surface and the first circuit layer. The solder ball disposing surface structure includes: metal pads integral to the second circuit layer; metal flanges formed around the metal pads; and a second insulative protection layer formed on the solder ball disposing surface, the second insulative protection layer having second openings each with a size smaller than an outer diameter of each of the metal flanges so as to expose a part of surfaces of the metal flanges, thereby increasing contact area of the surface for mounting conductive elements and preventing detachment of the conductive elements from the surface due to poor bonding force.

### CROSS REFERENCE TO RELATED APPLICATION

This application is related to the disclosure of Taiwanese Patent Application Number 096135299 filed on Sep. 21, 2007, the disclosure of which is expressly incorporated herein by reference in its entirety.

### FIELD OF THE INVENTION

The present invention relates generally to a solder ball disposing surface structure of a package substrate, and more particularly to a package substrate with metal flanges formed on electrical connecting pads thereof.

### BACKGROUND

Along with the rapid development of the electronic industries, the present electronic products are developed towards multi-function and high performance. To meet requirements of semiconductor packages for high integration and miniaturization, package substrates for carrying semiconductor chips have been developed from single layer boards to multi-layer boards. Meanwhile, interlayer connection techniques have been used to increase available circuit layout area in a limited space, thereby meeting requirements of high-density integrated circuits.

The present package substrates for carrying semiconductor chips comprise wire bonding package substrates, chip scale package (CSP) substrates, flip chip ball grid array (FCBGA) package substrates and so on. FIG. 1 exemplifies a conventional flip-chip package substrate. As shown in FIG. 1, a package substrate 11 is provided, which comprises a first surface 11a for chip mounting and a second surface 11b for solder ball attachment. A plurality of first electrical connecting pads 111 to be electrically connected with a semiconductor chip 12 are formed on the first surface 11a, and a plurality of first conductive elements 13a made of solder material are formed on surface of the first electrical connecting pads 111. Further, a plurality of second electrical connecting pads 112 to be electrically connected with other electronic device such as a printed circuit board are formed on the second surface 11b, and a plurality of second conductive elements 13b made of solder material are formed on surface of the second electrical connecting pads 112. The semiconductor chip 12 has a plurality of electrode pads 121. Metal bumps 14 are formed on the surface of each of the electrode pads 121 in a flip-chip manner and corresponding in position to the first conductive elements 13a of the package substrate 11. Then at a reflow temperature capable of melting the first conductive elements 13a, the first conductive elements 13a are reflowed to the corresponding metal bumps 14, thereby electrically connecting the semiconductor chip 12 to the package substrate 11.

However, as the contact area between the second electrical connecting pads 112 on the second surface 11b of the package substrate 11 and the corresponding second conductive elements 13b is only limited to the exposed area of the second electrical connecting pads 112, the bonding force between the second conductive elements 13b and the second electrical connecting pads 112 can be poor due to insufficient contact area therebetween, and accordingly the second conductive elements 13b can easily detach from the second electrical connecting pads 112. For example, if the pitch between the second electrical connecting pads 112 is decreased from 800 μm to 400 μm, and the diameter of each of the openings for the second electrical connecting pads 112 is decreased from 500 μm to 250 μm, the contact area will be decreased to one-fourth of the initial contact area, which thus seriously reduces the bonding force between the conductive elements and the electrical connecting pads.

FIGS. 2A to 2E are diagrams showing a conventional method for increasing the contact area between the conductive elements and the electrical connecting pads on the solder ball disposing surface of a package substrate. As shown in FIG. 2A, the solder ball disposing surface of the package substrate 20 is formed with electrical connecting pads 201. An insulative protection layer 21 is formed on the solder ball disposing surface and the electrical connecting pads 201, and a plurality of openings 210 is formed in the insulative protection layer 21 for exposing a part of the surface of the electrical connecting pads 201. As shown in FIG. 2B, a conductive layer 22 is formed on the insulative protection layer 21 and the exposed surface of the electrical connecting pads 201. As shown in FIG. 2C, a resist layer 23 is formed on the conductive layer 22, and a plurality of ring-shaped openings 230 is formed in the resist layer 23 by exposure and development so as to expose the conductive layer 22 on the electrical connecting pads 201 around the openings 210 of the insulative protection layer 21. As shown in FIG. 2D, by using the conductive layer 22 as a current conductive path for electroplating, flanges 24 are formed in the ring-shaped openings 230, the flanges 24 being attached to periphery of the openings 210 of the insulative protection layer 21. Finally, the resist layer 23 and the conductive layer 22 covered by the resist layer 23 are removed so as to expose the flanges 24 and a part of the surface of the electrical connecting pads 201.

However, since the conductive layer 22 is left between the flanges 24 and the electrical connecting pads 201, the bonding strength between the flanges 24 and the electrical connecting pads 201 is reduced. In addition, as the formed flanges 24 are attached to the periphery of the openings 210 of the insulative protection layer 21, the present method provides only a limited increase of the contact area for the conductive elements such as solder balls subsequently formed on the electrical connecting pads 201 and the flanges 24. As a result, detaching of the solder balls still can easily occur. Therefore, how to provide a structure capable of increasing the bonding force between solder balls and electrical connecting pads on the solder ball disposing surface of a package substrate so as to avoid detaching of the solder balls from the electrical connecting pads caused by reduced bonding area has become urgent.

### SUMMARY

According to the above drawbacks, an objective of the present invention is to provide a solder ball disposing surface structure of a package substrate through which contact area of the surface structure for mounting conductive elements can be increased.

Another objective of the present invention is to provide a solder ball disposing surface structure of a package substrate through which the bonding force between the solder ball disposing surface structure and the conductive elements can be increased.

In order to attain the above and other objectives, the present invention discloses a solder ball disposing surface structure of a package substrate, wherein the package substrate has a chip disposing surface with a first circuit layer and an opposed solder ball disposing surface with a second circuit layer, a first insulative protection layer being formed on the chip disposing surface and the first circuit layer. The solder ball disposing surface structure comprises: metal pads, which are a part of the second circuit layer; metal flanges disposed around the metal pads; and a second insulative protection layer formed on the solder ball disposing surface, the second insulative protection layer having second openings with a size smaller than outer diameter of the metal flanges so as to expose a part of the surface of the metal flanges.

The present invention discloses another solder ball disposing surface structure of a package substrate, wherein the package substrate has a chip disposing surface with a first circuit layer and an opposed solder ball disposing surface with a second circuit layer, a first insulative protection layer being formed on the chip disposing surface and the first circuit layer. The solder ball disposing surface structure comprises: metal pads, which are a part of the second circuit layer; metal flanges disposed around the metal pads; and a second insulative protection layer formed on the solder ball disposing surface, the second insulative protection layer having second openings with a size bigger than the metal pads so as to expose the metal flanges and the metal pads.

According to the above-described structures, a surface treatment layer or conductive elements can be disposed on the metal pads and the metal flanges. The surface treatment layer may be one of an OSP (Organic solderability preservatives) layer, a Ni/Au layer, a Ni/Pd/Au layer and a Sn/Pb layer. Alternatively, the surface treatment layer may be made of one of the group consisting of Au, Ag, Sn and Cu. The conductive elements are solder balls. A conductive layer can be disposed between the substrate surface and the metal pads.

The second openings have a size not bigger than outer diameter of the metal flanges, or the second openings have a size bigger than outer diameter of the metal pads. The core board can be a two-layer or multi-layer circuit board with a dielectric layer on surface thereof or an insulating board. The outer diameter of the metal flanges is not bigger than that of the metal pads.

The above-described structures further comprise a metal layer disposed on the metal pads inside the metal flanges. A surface treatment layer is disposed on the metal flanges and the metal layer. The surface treatment layer may be one of an OSP layer, a Ni/Au layer, a Ni/Pd/Au layer and a Sn/Pb layer. Alternatively, the surface treatment layer may be made of one of the group consisting of Au, Ag, Sn and Cu. The above-described structures further comprise conductive elements of solder balls that are disposed on the surface treatment layer or disposed on the metal flanges and the metal layer.

According to the present invention, since metal flanges are formed on the metal pads of the solder ball disposing surface of a package substrate, contact area of the metal pads is increased. In addition, the bonding area for conductive elements on electrical connecting pads can further be increased by adjusting type of openings in the insulative protection layer. Moreover, since no conductive layer is formed between the metal pads and the metal flanges as in the prior art, the bonding strength between the metal pads and the metal flanges is improved, thereby preventing detaching of the conductive elements subsequently formed on the metal pads and the metal flanges.

### BRIEF DESCRIPTION OF DRAWINGS

FIG. 1 is a diagram of a conventional package substrate with a semiconductor chip disposed thereon;

FIGS. 2A to 2E are sectional diagrams showing a conventional method for forming flanges on electrical connecting pads of a package substrate;

FIGS. 3A to 3H are sectional diagrams showing a manufacturing method of a solder ball disposing surface structure of a package substrate according to a first embodiment of the present invention, wherein FIG. 3F′ is another embodiment of FIG. 3F and FIG. 3H′ is another embodiment of FIG. 3H;

FIGS. 4A to 4G are sectional diagrams showing a manufacturing method of a solder ball disposing surface structure of a package substrate according to a second embodiment of the present invention;

FIG. 4G′ is another embodiment of FIG. 4G;

FIG. 5A is a diagram showing a solder ball disposing surface structure with a surface treatment layer disposed on the metal pads and the metal flanges of SMD pads;

FIG. 5B is a diagram showing a solder ball disposing surface structure with conductive elements disposed on the surface treatment layer of FIG. 5A;

FIG. 5C is a diagram showing a solder ball disposing surface structure with conductive elements disposed on the metal pads and the metal flanges of SMD pads;

FIG. 6A is a diagram showing a solder ball disposing surface structure with a surface treatment layer disposed on the metal pads and the metal flanges of NSMD pads;

FIG. 6B is a diagram showing a solder ball disposing surface structure with conductive elements disposed on the surface treatment layer of FIG. 6A; and

FIG. 6C is a diagram showing a solder ball disposing surface structure with conductive elements disposed on the metal pads and the metal flanges of NSMD pads.

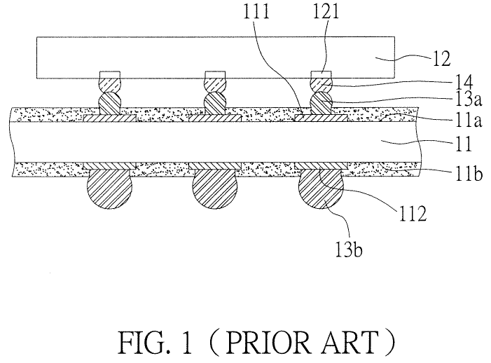

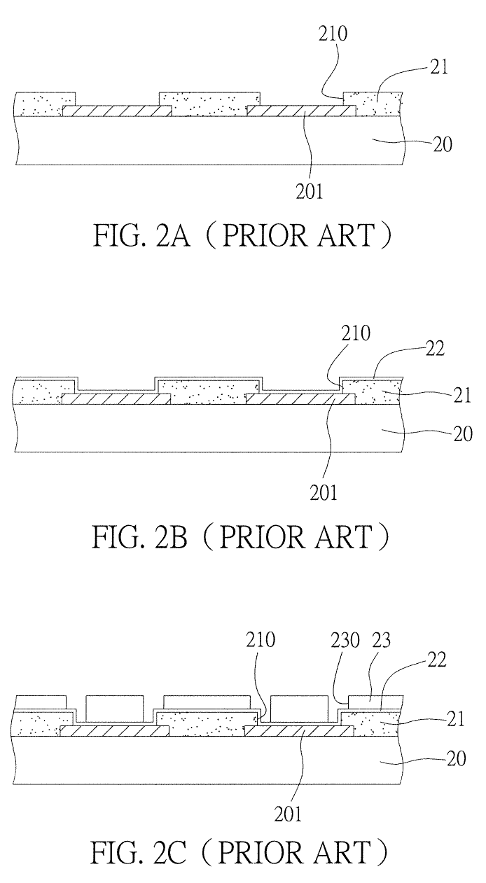

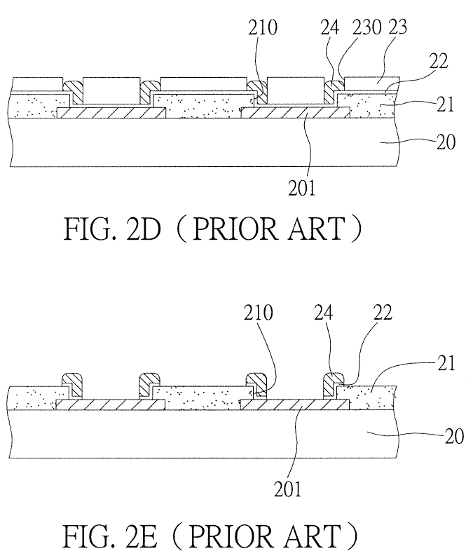

### DETAILED DESCRIPTION

The following illustrative embodiments are provided to illustrate the disclosure of the present invention, these and other advantages and effects can be apparent to those skilled in the art after reading the disclosure of this specification.

### First Embodiment

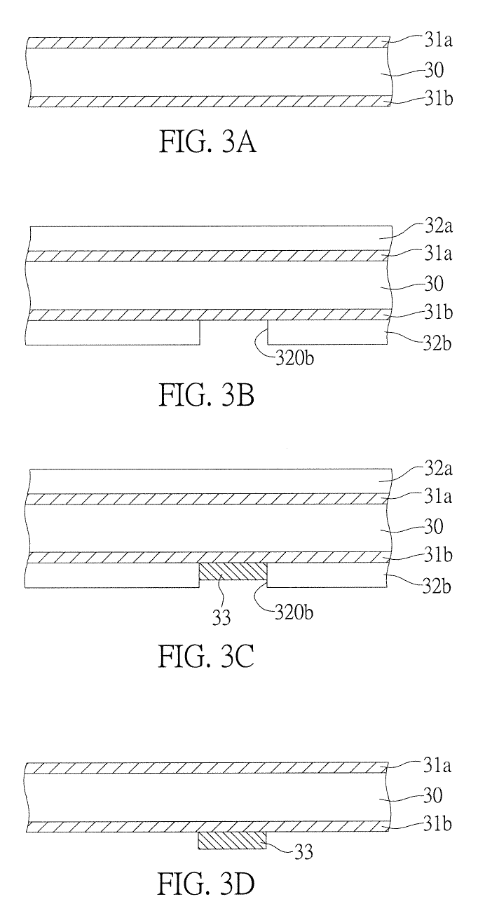

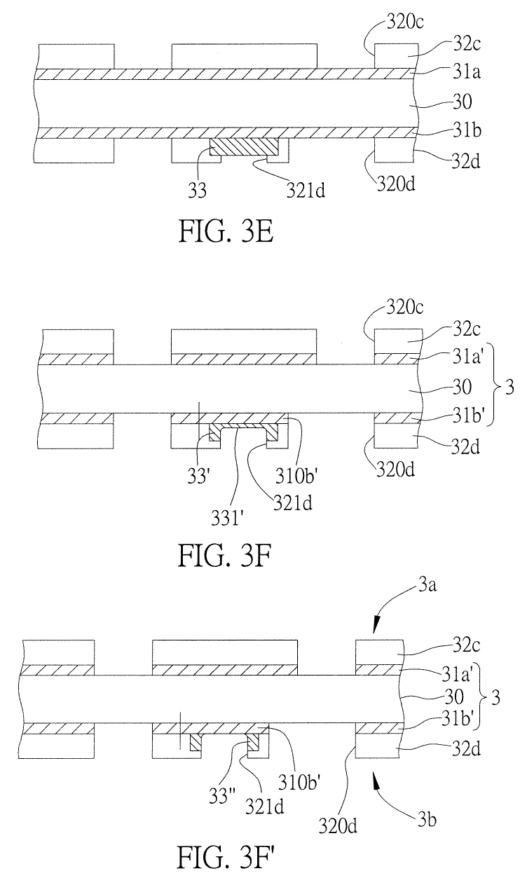

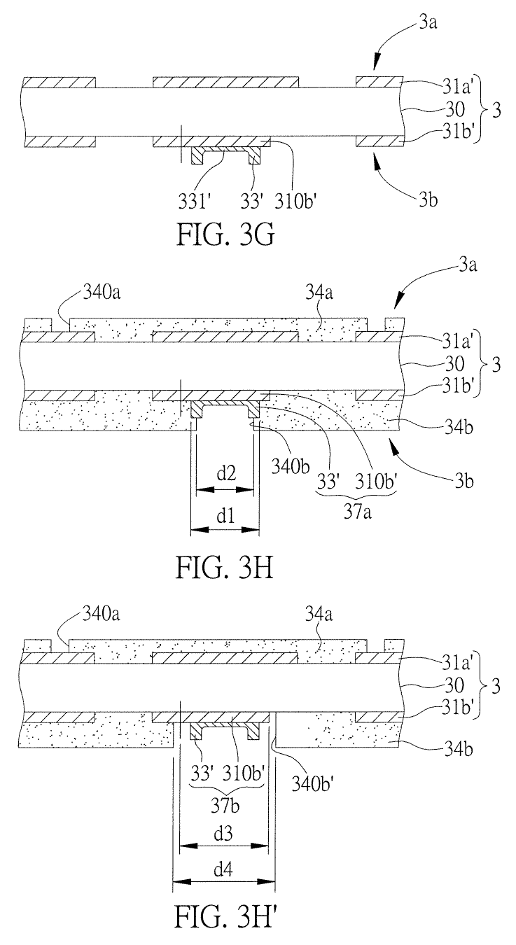

FIGS. 3A to 3H are sectional diagrams showing a manufacturing method of a solder ball disposing surface structure of a package substrate according to a first embodiment of the present invention.

As shown in FIG. 3A, a core board 30 with a first metal layer 31a and a second metal layer 31b respectively formed on two opposite surfaces thereof is provided. The core board 30 can be a two-layer or multi-layer circuit board with a dielectric layer on surface thereof or an insulating board. Since the manufacturing technique of circuit boards is well known in the art and not characteristic of the present invention, detailed description thereof is omitted.

As shown in FIG. 3B, a first resist layer 32a and a second resist layer 32b are formed on the first metal layer 31a and the second metal layer 31b, respectively. The first and second resist layers 32a, 32b can be such as a dry film or liquid photoresist, which is formed on the first and second metal layers 31a, 31b by printing, spin coating or attaching and then patterned by exposure and development so as to form second openings 320b in the second resist layer 32b for exposing a part of the surface of the second metal layer 31b.

As shown in FIG. 3C, by using the second metal layer 31b as a current conductive path for electroplating, metal bumps 33 are formed on the second metal layer 31b exposed from the second openings 320b of the second resist layer 32b.

As shown in FIG. 3D, the first and second resist layers 32a, 32b are removed so as to expose the first and second metal layers 31a, 31b and the metal bumps 33.

As shown in FIG. 3E, a third resist layer 32c is formed on the first metal layer 31a, and a plurality of third openings 320c is formed in the third resist layer 32c for exposing a part of the surface of the first metal layer 31a; and a fourth resist layer 32d is formed on the second metal layer 31b and the metal bumps 33, and fourth openings 320d are formed in the fourth resist layer 32d for exposing a part of the surface of the second metal layer 31b and fifth openings 321d are formed in the fourth resist layer 32d for exposing a part of the surface of the metal bumps 33.

As shown in FIGS. 3F and 3F′, the first metal layer 31a in the third openings 320c of the third resist layer 32c, the second metal layer 31b in the fourth openings 320d of the fourth resist layer 32d, as well as the metal bumps 33 in the fifth opening 321d are removed by etching, thereby forming a first circuit layer 31a′, a second circuit layer 31b′ and metal pads 310b′ on the two opposite surfaces of the core board 30, respectively. Therein, each metal bump 33 is partly removed so as to form a metal flange 33′ that is disposed around the metal pad 310b′ and meanwhile form a metal layer 331′ on the metal pad 310b′ inside the metal flange 33′, as shown in FIG. 3F. Alternatively, each metal bump 33 in the fifth opening 321d can be thoroughly removed, thereby only forming a metal flange 33″ that is disposed around the metal pad 310b′, as shown in FIG. 3F′. Thus, the core board 30, the first circuit layer 31a′ and the second circuit layer 31b′ constitute a package substrate 3, which has a chip disposing surface 3a with the first circuit layer 31a′ and an opposed solder ball disposing surface 3b with the second circuit layer 31b′.

As shown in FIG. 3G, the third and fourth resist layers 32c, 32d are removed so as to expose the first circuit layer 31a′, the second circuit layer 31b′, the metal pads 310b′ and the metal flanges 33′ disposed around the metal pads 310b′.

As shown in FIGS. 3H and 3H′, a first insulative protection layer 34a is formed on the core board 30 and the first circuit layer 31a′, and first openings 340a is formed in the first insulative protection layer 34a so as to expose a part of the surface of the first circuit layer 31a′ as electrical connecting pads for electrically connecting a semiconductor chip. A second insulative protection layer 34b is formed on the core board 30, the second circuit layer 31b′ and the metal pads 310b′, and the second insulative protection layer 34b has second openings 340b formed for exposing a part of the surface of the metal flanges 33′, wherein size d2 of the second openings 340b is smaller than outer diameter d1 of the metal flanges 33′ such that solder mask defined (SMD) pads 37a can be formed, as shown in FIG. 3H. Alternatively, as shown in FIG. 3H′, size d4 of the second openings 340b′ is bigger than size d3 of the metal pads 310b′ such that the metal pads 310b′ and the metal flanges 33′ can be exposed to form non solder mask defined (NSMD) pads 37b.

Thus, the present invention provides a solder ball disposing surface structure of a package substrate. As shown in FIG. 3H, the package substrate 3 has a chip disposing surface 3a with a first circuit layer 31a′ and a solder ball disposing surface 3b with a second circuit layer 31b′, a first insulative protection layer 34a being formed on the chip disposing surface 3a and the first circuit layer 31a′. The solder ball disposing surface structure comprises: metal pads 310b′, which are a part of the second circuit layer 31b′; metal flanges 33′ disposed around the metal pads 310b′; and a second insulative protection layer 34b formed on the solder ball disposing surface 3b and having second openings 340b.

According to the above structure, size of the second openings 340b can be smaller than outer diameter of the metal flanges 33′ so as to expose a part of the surface of the metal flanges 33′, thereby forming SMD pads 37a; or size of the second openings 340b′ can be bigger than that of the metal pads 310b′ so as to expose the metal pads 310b′ and the metal flanges 33′, thereby forming NSMD pads 37b. The metal flanges 33′ can have a shape of circle, ellipse, rectangle or irregular shape. The metal pads 310b′ can have a shape of circle, ellipse, rectangle or irregular shape. Outer diameter of the metal flanges 33′ is not bigger than that of the metal pads 310b′.

### Second Embodiment

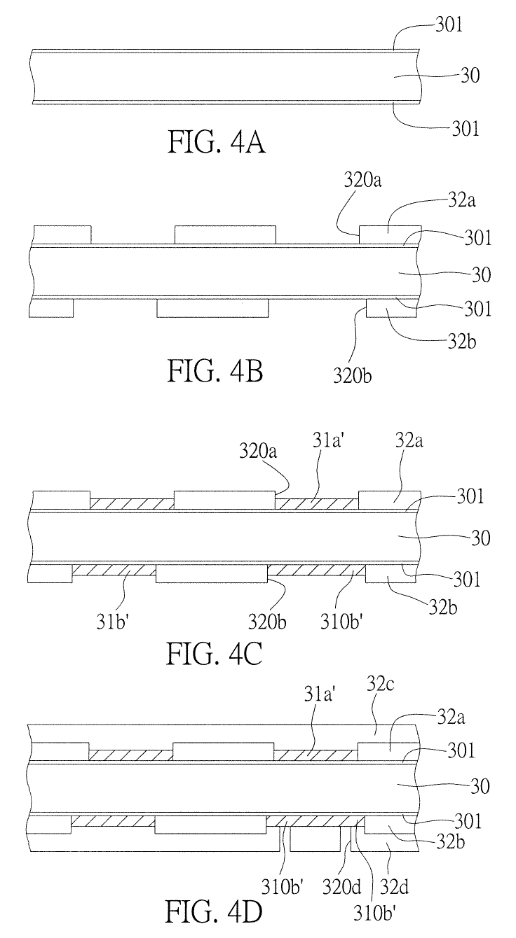

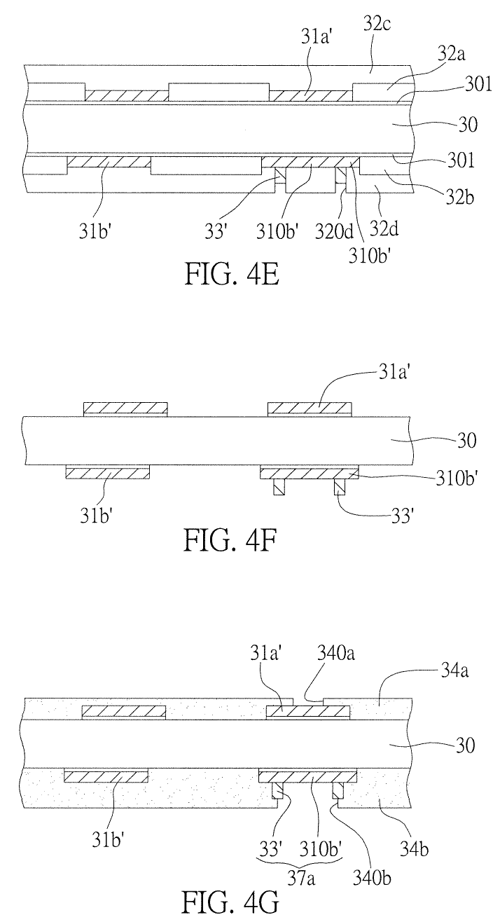

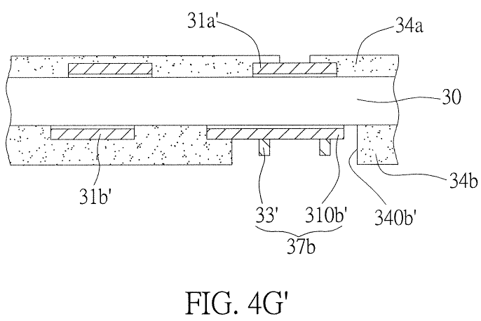

FIGS. 4A to 4G are sectional diagrams showing a manufacturing method of a solder ball disposing surface structure of a package substrate according to a second embodiment of the present invention.

As shown in FIG. 4A, a core board 30 with a conductive layer 301 formed on two opposite surfaces thereof is provided. The core board 30 can be an insulating board, a copper clad laminate board or a two-layer or multi-layer circuit board having dielectric layer on surface thereof. Since the manufacturing technique of circuit boards well known in the art and not characteristic of the present invention, detailed description thereof is omitted.

As shown in FIG. 4B, a first resist layer 32a and a second resist layer 32b are formed on the conductive layer 301 of the two opposite surfaces of the core board 30, respectively. The first and second resist layers 32a, 32b respectively have first openings 320a and second openings 320b for exposing a part of the surface of the conductive layer 301.

As shown in FIG. 4C, by using the conductive layer 301 as a current conductive path for electroplating, a first circuit layer 31a′ is formed in the first openings 320a of the first resist layer 32a and a second circuit layer 31b′ is formed in the second openings 320b of the second resist layer 32b, wherein the second circuit layer 31b′ has metal pads 310b′.

As shown in FIG. 4D, a third resist layers 32c is formed on surfaces of the first resist layer 32a and the first circuit layer 31a′, and a fourth resist layer 32d is formed on surfaces of the second resist layer 32b and the second circuit layer 31b′, wherein the fourth resist layer 32d has ring-shaped openings 320d for exposing a part of the surface of the metal pads 310b′.

As shown in FIG. 4E, by using the conductive layer 301 as a current conductive path for electroplating, metal flanges 33′ are formed on the surface of the metal pads 310b′.

As shown in FIG. 4F, the third resist layer 32c, the first resist layer 32a and the conductive layer 301 covered by the first resist layer 32a, the fourth resist layer 32d, the second resist layer 32b and the conductive layer 301 covered by the second resist layer 32b are removed so as to expose the first circuit layer 31a′, the second circuit layer 31b′ and the metal flanges 33′ on the metal pads 310b′.

As shown in FIGS. 4G and 4G′, a first insulative protection layer 34a is formed on the core board 30 and the first circuit layer 31a′, and the first insulative protection layer 34a has first openings 340a formed so as to expose a part of the surface of the first circuit layer 31a′ as electrical connecting pads for electrically connecting a semiconductor chip. A second insulative protection layer 34b is formed on the core board 30, the second circuit layer 31b′ and the metal pads 310b′, and the second insulative protection layer 34b has second openings 340b formed for exposing a part of the surface of the metal flanges 33′, wherein size of the second openings 340b is smaller than outer diameter of the metal flanges 33′ such that solder mask defined (SMD) pads 37a can be formed, as shown in FIG. 4G. Alternatively, as shown in FIG. 4G′, size of the second openings 340b′ is bigger than that of the metal pads 310b′ such that the metal pads 310b′ and the metal flanges 33′ can be exposed to form non solder mask defined (NSMD) pads 37b. The metal flanges 33′ can have a shape of circle, ellipse, rectangle or irregular shape. The metal pads 310b′ can have a shape of circle, ellipse, rectangle or irregular shape. Outer diameter of the metal flanges 33′ is not bigger than that of the metal pads 310b′.

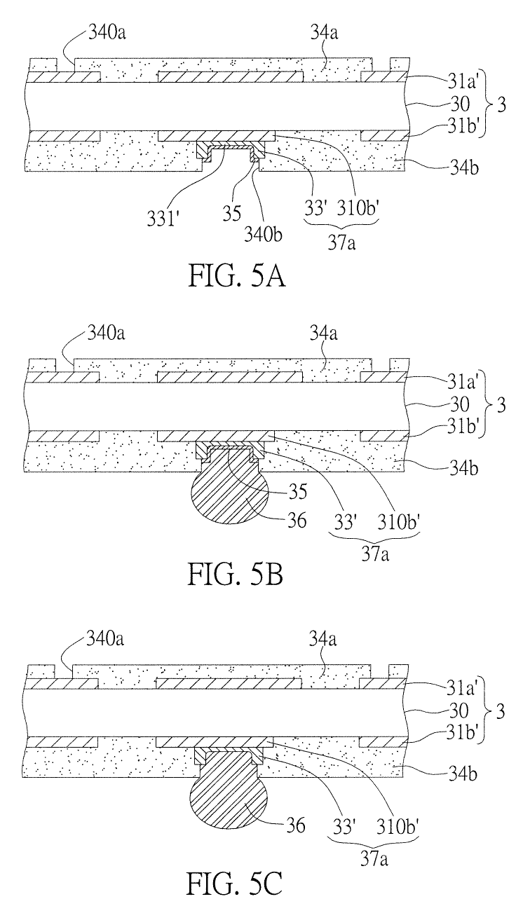

Referring to FIGS. 5A to 5C, a surface treatment layer 35 is further formed on the SMD pads 37a. The surface treatment layer 35 may be one of an OSP layer, a Ni/Au layer, a Ni/Pd/Au layer and a Sn/Pb layer. Alternatively, the surface treatment layer 35 may be made of one of the group of consisting of Au, Ag, Sn and Cu. As shown in FIG. 5B, conductive elements 36 of solder balls are further formed on the surface treatment layer 35. Alternatively, as shown in FIG. 5C, conductive elements 36 of solder balls are formed on the SMD pads 37a.

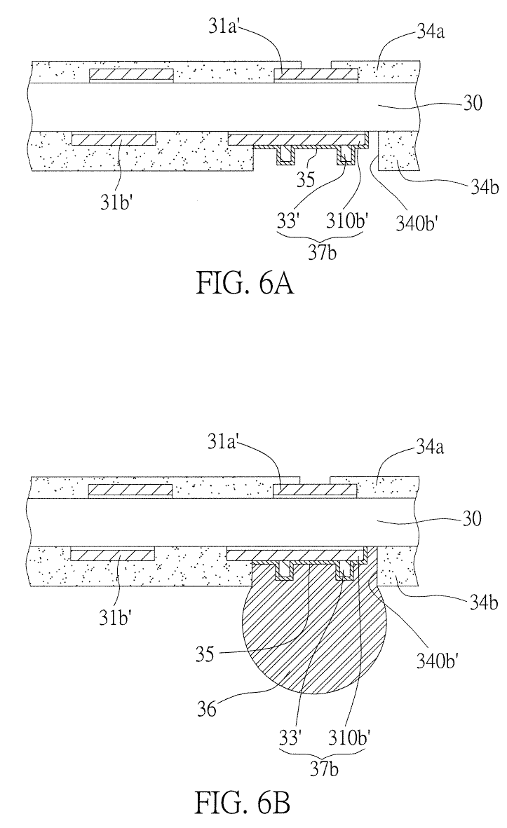

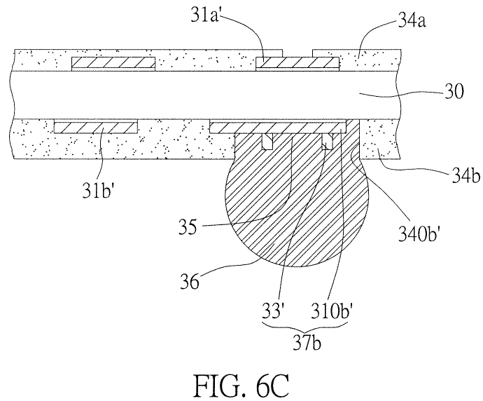

Referring to FIGS. 6A to 6C, a surface treatment layer 35 is formed on the NSMD pads 37b. The surface treatment layer 35 may be one of an OSP layer, a Ni/Au layer, a Ni/Pd/Au layer and a Sn/Pb layer. Alternatively, the surface treatment layer 35 may be made of one of the group of consisting of Au, Ag, Sn and Cu. As shown in FIG. 6B, conductive elements 36 of solder balls are further formed on the surface treatment layer 35. Alternatively, as shown in FIG. 6C, conductive elements 36 of solder balls are formed on the NSMD pads 37b.

According to the present invention, metal flanges are formed on the metal pads of the solder ball disposing surface of a package substrate, thereby increasing the contact area of the metal pads. In addition, the bonding area for conductive elements on electrical connecting pads can further be increased by adjusting type of openings in the insulative protection layer. Moreover, since no conductive layer is formed between the metal pads and the metal flanges as in the prior art, the bonding strength between the metal pads and the metal flanges is improved, thereby preventing detaching of the conductive elements subsequently formed on the metal pads and the metal flanges.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A solder ball disposing surface structure of a package substrate, wherein the package substrate has a chip disposing surface with a first circuit layer, an opposed solder ball disposing surface with a second circuit layer, and a first insulative protection layer formed on the chip disposing surface and the first circuit layer, the solder ball disposing surface structure comprising:
metal pads, integrate with the second circuit layer;
metal flanges formed around the metal pads; and
a second insulative protection layer formed on the solder ball disposing surface, the second insulative protection layer having second openings each with a size smaller than an outer diameter of each of the metal flanges so as to expose a part of surfaces of the metal flanges.

2. The solder ball disposing surface structure of claim 1, wherein the outer diameter of each of the metal flanges is not greater than that of each of the metal pads.

3. The solder ball disposing surface structure of claim 1, further comprising a metal layer formed on the metal pads inside the metal flanges.

4. The solder ball disposing surface structure of claim 3, further comprising a surface treatment layer formed on the metal flanges and the metal layer.

5. The solder ball disposing surface structure of claim 4, wherein the surface treatment layer is one of an OSP layer, a Ni/Au layer, a Ni/Pd/Au layer and a Sn/Pb layer.

6. The solder ball disposing surface structure of claim 4, wherein the surface treatment layer is made of a material selected form the group consisting of Au, Ag, Sn and Cu.

7. The solder ball disposing surface structure of claim 4, further comprising conductive elements of solder balls formed on the surface treatment layer.

8. The solder ball disposing surface structure of claim 3, further comprising conductive elements of solder balls formed on the metal flanges and the metal layer.

9. The solder ball disposing surface structure of claim 1, further comprising a surface treatment layer formed on the metal pads and the metal flanges.

10. The solder ball disposing surface structure of claim 1, further comprising a conductive layer formed between the substrate surface and the metal pads.

11. A solder ball disposing surface structure of a package substrate, wherein the package substrate has a chip disposing surface with a first circuit layer, an opposed solder ball disposing surface with a second circuit layer, and a first insulative protection layer formed on the chip disposing surface and the first circuit layer, the solder ball disposing surface structure comprising:
metal pads, which are a part of the second circuit layer;
metal flanges formed around the metal pads; and
a second insulative protection layer formed on the solder ball disposing surface, the second insulative protection layer having second openings each with a size bigger each of than the metal pads so as to expose the metal flanges and the metal pads.

12. The solder ball disposing surface structure of claim 11, wherein an outer diameter of each of the metal flanges is not greater than that of each of the metal pads.

13. The solder ball disposing surface structure of claim 11, further comprising a metal layer formed on the metal pads inside the metal flanges.

14. The solder ball disposing surface structure of claim 13, further comprising a surface treatment layer formed on the metal flanges, the metal layer and the metal pads.

15. The solder ball disposing surface structure of claim 14, further comprising conductive elements of solder balls formed on the surface treatment layer.

16. The solder ball disposing surface structure of claim 13, further comprising conductive elements of solder balls formed on the metal flanges and the metal pads.

17. The solder ball disposing surface structure of claim 11, further comprising a surface treatment layer formed on the metal pads and the metal flanges.

18. The solder ball disposing surface structure of claim 17, further comprising conductive elements of solder balls disposed on the surface treatment layer.

19. The solder ball disposing surface structure of claim 11, further comprising conductive elements of solder balls formed on the metal pads and the metal flanges.

20. The solder ball disposing surface structure of claim 11, further comprising a conductive layer formed between the substrate surface and the metal pads.
